(19) United States
(12) Patent Application Publication
(10) Pub. No.: US 2012/0261746 A1
(43) Pub. Date: Oct. 18, 2012

(54) Double-Trench Vertical Devices and Methods with Self-Alignment Between Gate and Body Contact

(75) Inventors: Mohamed N. Darwish, Campbell, CA (US); Zeng Jun, Torrance, CA (US); Richard A. Blanchard, Los Altos, CA (US)

(73) Assignee: MAXPOWER SEMICONDUCTOR, INC., Santa Clara, CA (US)

(21) Appl. No.: 13/418,615

(22) Filed: Mar. 13, 2012

Related U.S. Application Data
(60) Provisional application No. 61/452,291, filed on Mar. 14, 2011.

(51) Int. Cl. H01L 29/78; H01L 21/336

(52) U.S. Cl. 257/330; 438/270; 257/E21.41; 257/E29.262

(57) ABSTRACT

Methods and resulting device structures for power trench transistor fabrication, wherein a reachup pillar from the field plate trench is left in place to define the location of a self-aligned contact to the field plate.

### CROSS-REFERENCE

Priority is claimed from U.S. application 61/452,291 filed Mar. 14, 2011, which is hereby incorporated by reference.

### BACKGROUND

The present application relates to semiconductor device fabrication, and more particularly to fabrication of devices which include transistor gates in one type of trench, and field plates in another.

Note that the points discussed below may reflect the hindsight gained from the disclosed inventions, and are not necessarily admitted to be prior art.

Power MOSFETs are widely used as switching devices in many electronic applications. In order to minimize conduction power loss, it is desirable that power MOSFETs have low specific on-resistance Rsp which is defined as the product of on-resistance times area.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 shows an innovative device.

FIGS. 2A and 2B show conventional structures.

FIGS. 3A-3H show further innovative device embodiments.

FIGS. 4A and following show a process sequence for building semiconductor devices as described.

FIGS. 5A and following show a process sequence for building semiconductor devices as described.

FIGS. 6A and following show a process sequence for building semiconductor devices as described.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application discloses new approaches to power devices which include trench transistors, and particularly to structures which include active gates in some trenches, and field plates in other trenches.

The inventors have realized that density can be improved by avoiding the need for a contact alignment tolerance where contact is made to the field plate trenches. Accordingly, the present application teaches that a pillar can be left in place over the field plate trench, to be used later to define the location of a contact to the field plate. The same self-alignment relation also defines the location of the p+ body contact diffusion. This saves a mask, but more importantly it removes an alignment tolerance from the pitch of the repeating pattern of transistors. A tighter pitch means that the benefits of the RFP structure can be obtained while still obtaining a good current density (high on-state conductivity).

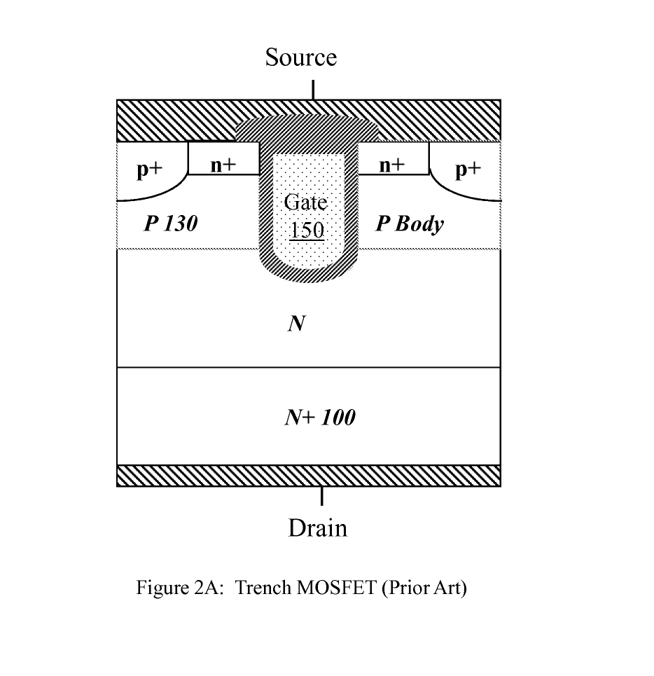

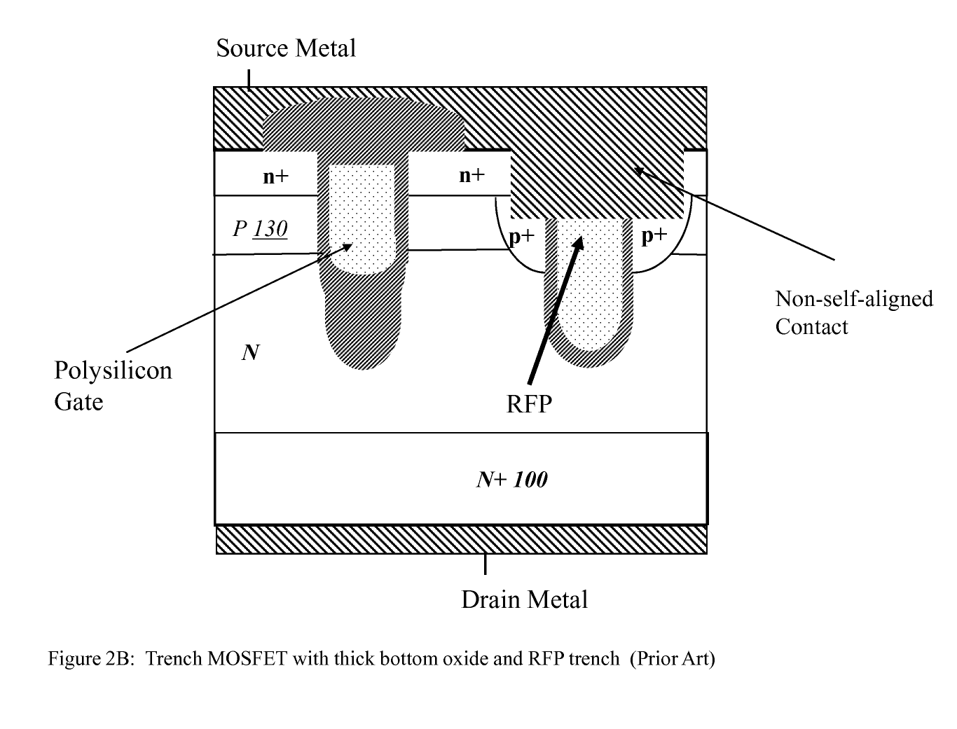

A schematic cross section of a conventional trench MOSFET is shown in FIG. 2A. A trench MOSFET provides a lower specific on-resistance Rsp as the cell pitch decrease due to high packing density or number of cells per unit area. As the cell density increases the associated capacitances (such as gate-drain capacitance Cgd and gate-source capacitance Cgs) also increase. To minimize switching losses it is desirable to have a switch with lower capacitances Cgd and gate-source Cgs or gate-drain charge Qgd and gate charge Qg.

The present inventors have previously disclosed a Recessed Field Plate (RFP) trench MOSFET structure with thick oxide formed at the bottom of the gate trench as shown in FIG. 2B. This provides lower Qgd and Qg.

Other structures with Embedded Recessed Field Plate (ERFP), where an insulator layer separates the recessed field plate and the contact, were also disclosed, and offer additional benefits. The misalignment between the contact and trench of the gate sets a constraint on achieving higher cell density transistor. As the trench and contact widths become narrower, the structure shown in FIG. 2B becomes increasingly unsuitable to achieve the highest cell densities.

There are two kinds of problems which can result from misalignment between the body contact and the gate trench. If the p+ body contact doping is too close to the gate trench, dopant diffusion into the body region near the active gate can raise the threshold voltages. This is very undesirable. If the body contact doping is farther from the gate trench than expected, this reduces the ruggedness of the device. This leads to an increase in the base series resistance of a parasitic npn bipolar transistor formed by the n+ source, p-body region and n drain region. This makes it more likely that a transient voltage can trigger the device into a second breakdown mode, where current flow can be sufficient to destroy the device. Misalignment will often lead to both these effects, since a misaligned contact can be too close to the gate trench on one side while being excessively far from the gate trench on the other side.

The present application discloses techniques and structures wherein power MOS transistors using RFP or ERFP techniques can have a self-aligned contact which was not previously possible. This removes an alignment tolerance from the pitch of the repeating pattern of transistors.

Note that the field plate contact and the body contact are both self-aligned. This means that the spacing from gate trench to field trench is strictly defined by the initial lithography in which both types of trenches are patterned simultaneously. Since NO alignment tolerance varies the spacing from the p+ body contact to the channel of the active device, there is no uncertainty, and no variation in threshold voltage due to variation of this spacing.

Moreover, the series resistance to the body (base of parasitic npn transistor) is reliably low, which helps improve the ruggedness of the device.

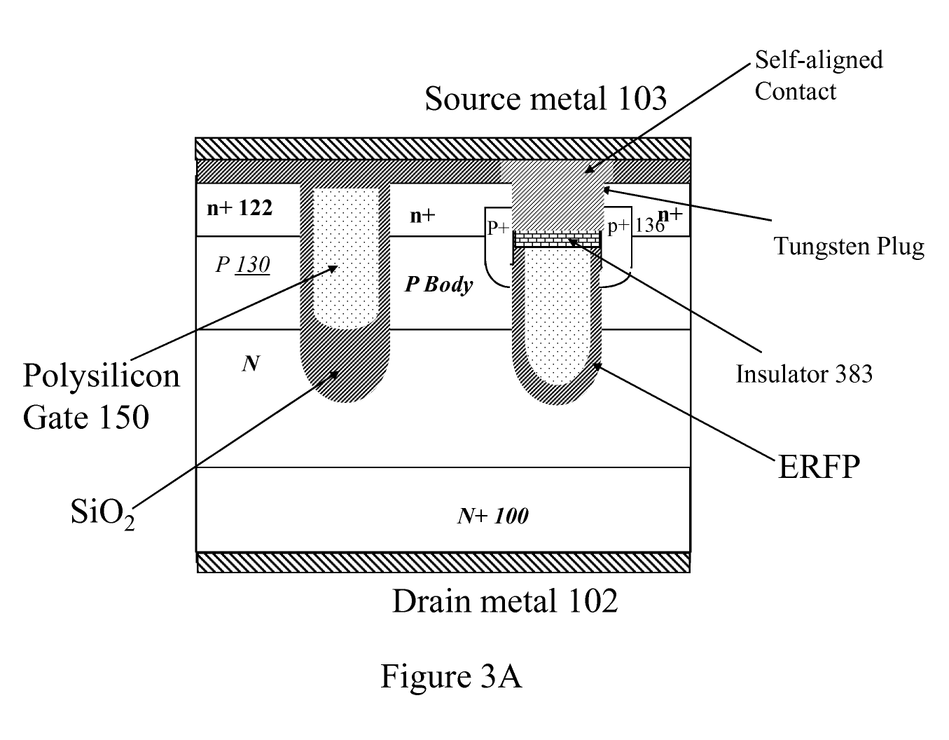

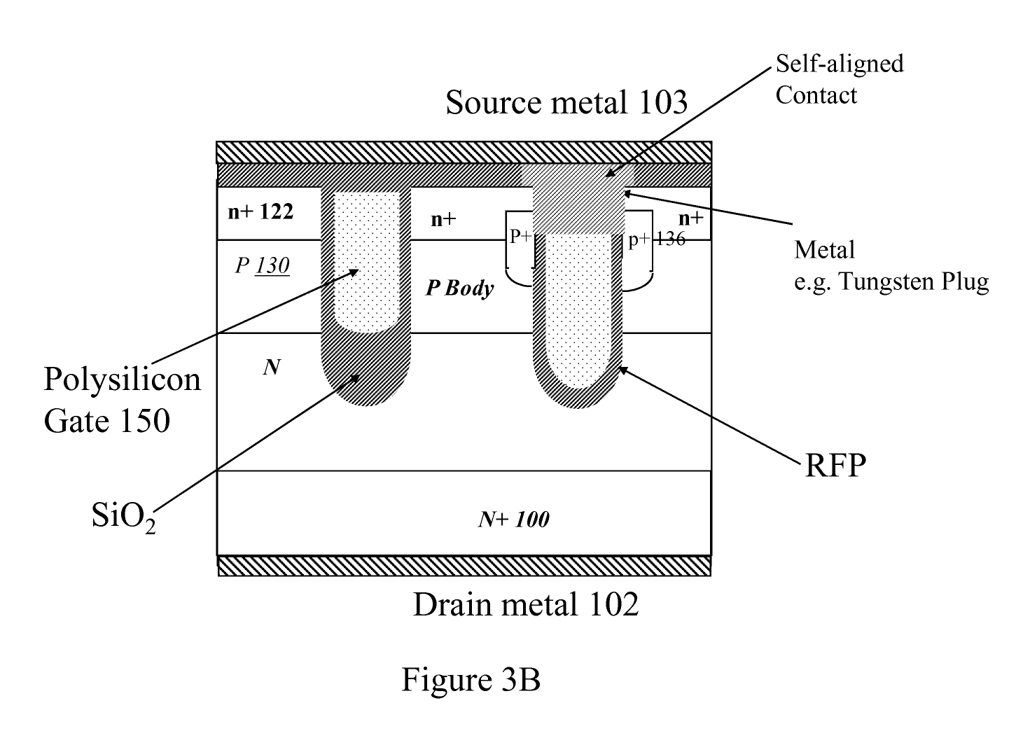

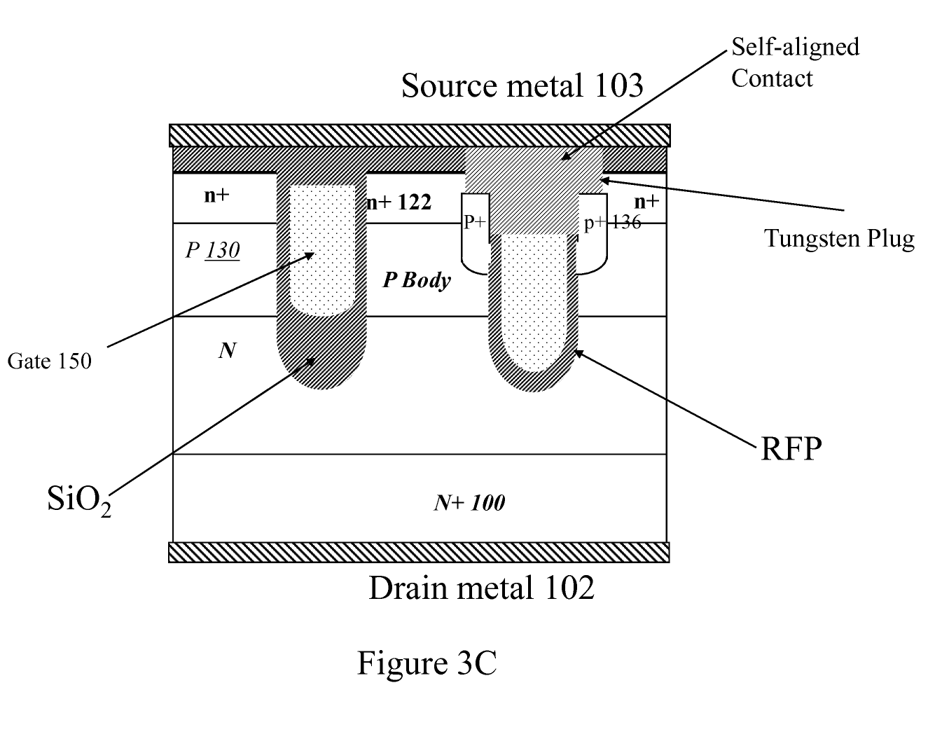

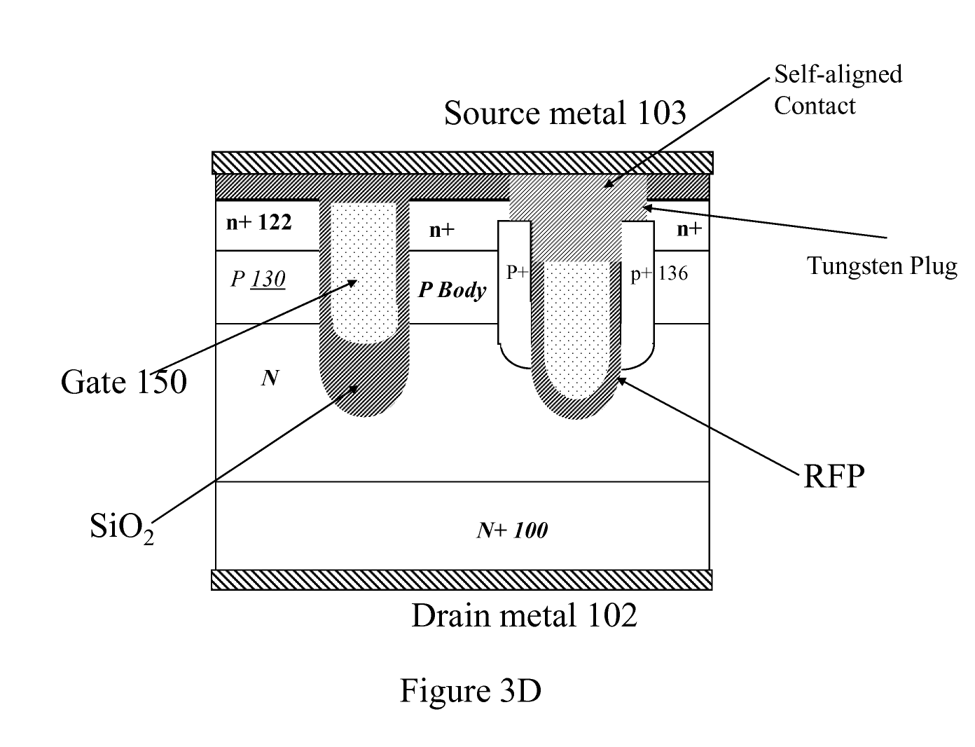

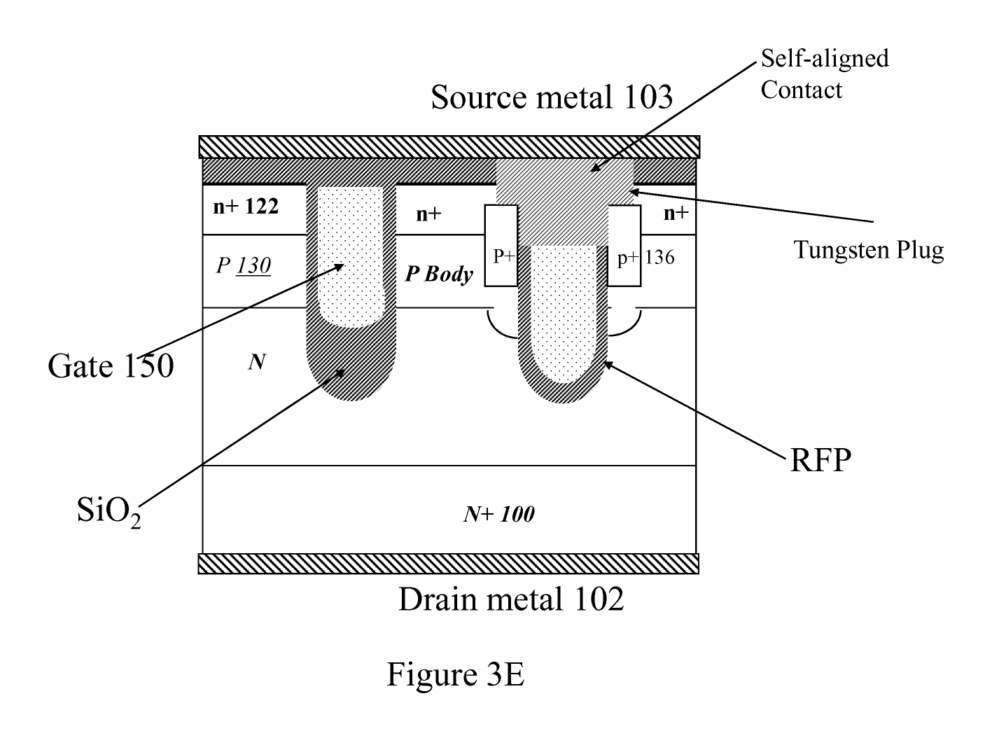

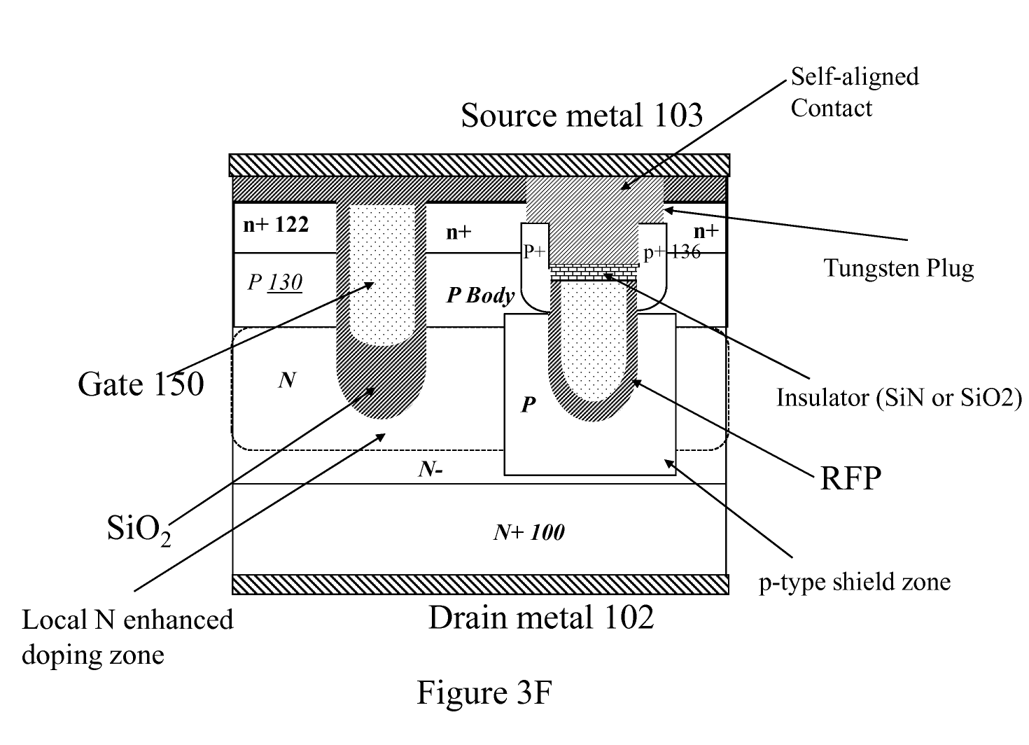

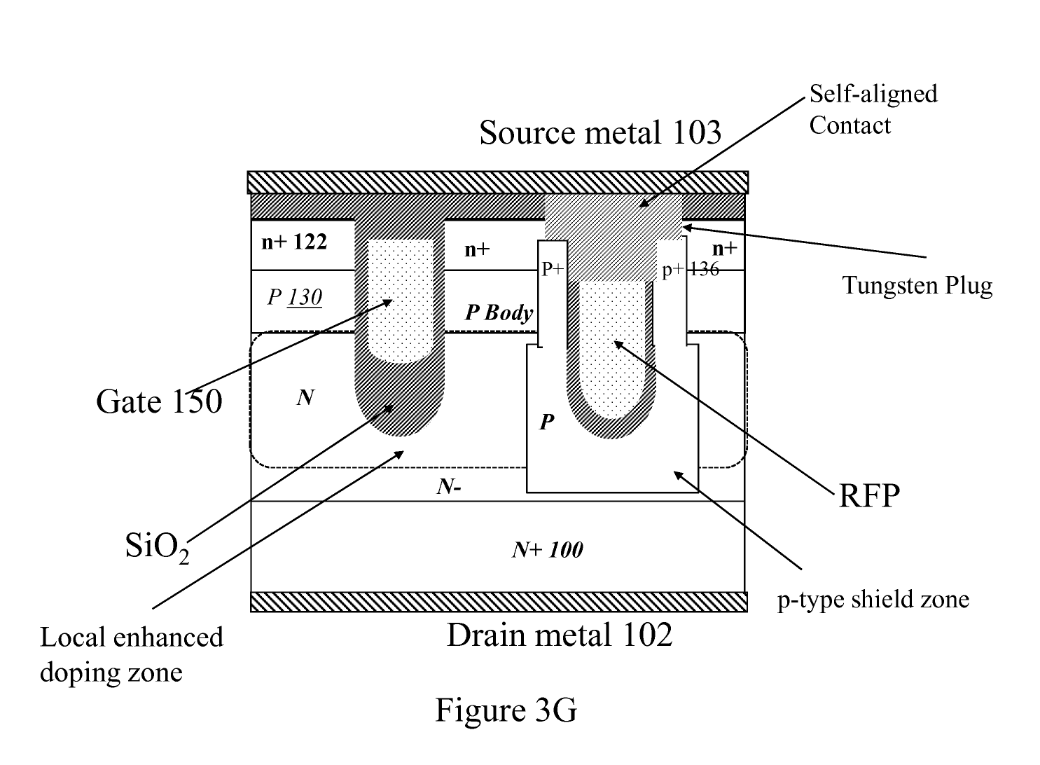

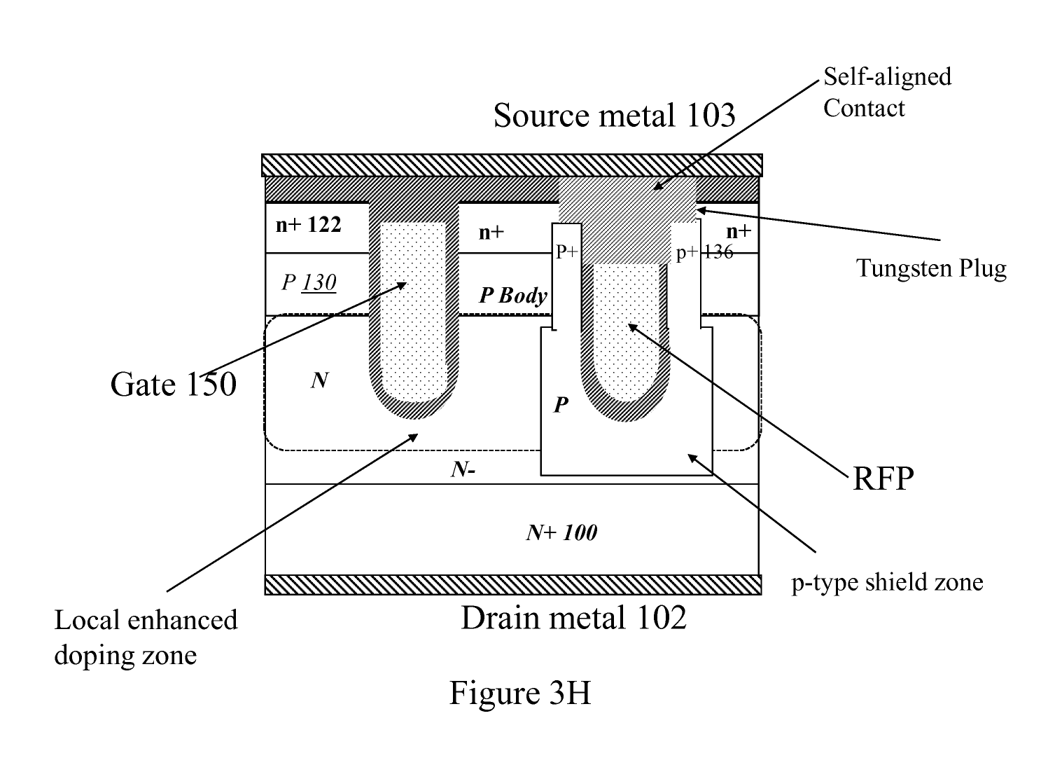

With the disclosed inventions, power MOSFET structures provide improved conduction and switching power losses. Trench MOSFET structures with RFP and self-aligned contact as shown in FIGS. 3A-3H provide reduced specific on-resistance Rsp due to the higher cell density and lower Qg and Qgd due to the RFP effect.

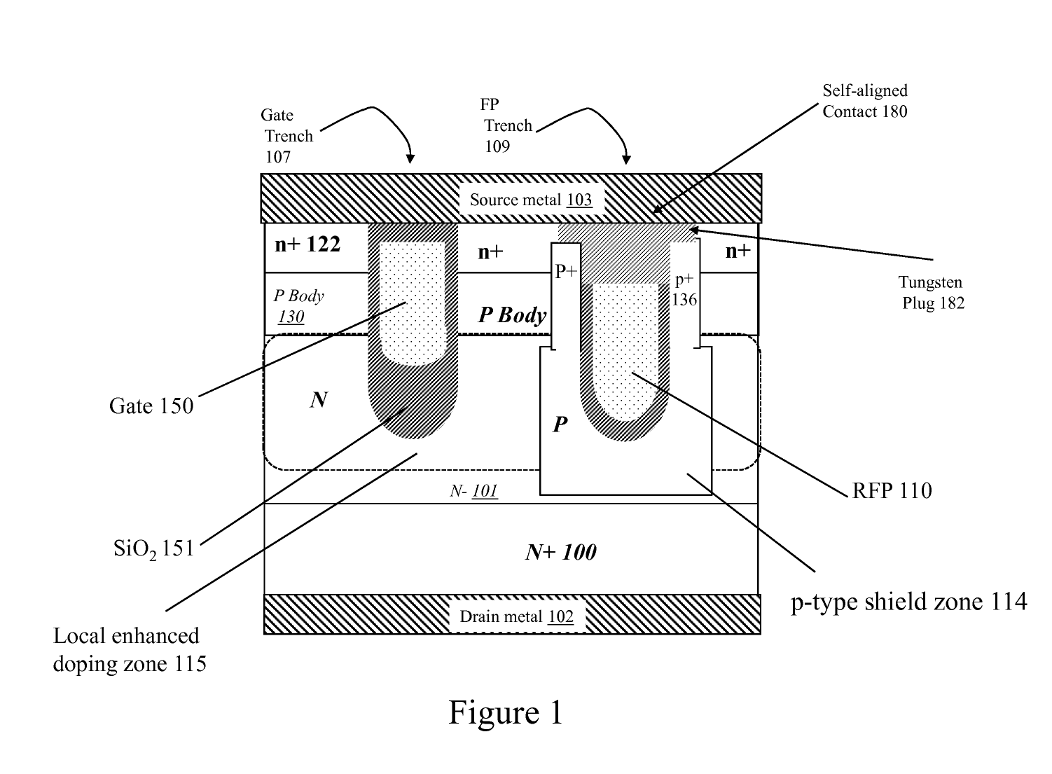

FIG. 1 shows an innovative device structure which includes p+ body contact regions 136 which surround a field plate tranch 109, but are completely self-aligned to the gate trench 107. The self-aligned contact 180, in this example, makes contact to a tungsten plug 182. (As discussed below, the tungsten plug does not have to contact the field plate 110 at all locations.) Gate electrode 150, when connected to a sufficiently positive voltage, inverts nearby portions of p-type body region 130 to permit electrons to flow from n+source region 122 down through the n-type epitaxial layer 101 (including the enhanced doping zone 115 in this example) to n+ substrate 100. The field plate electrode 110 and gate electrode 150 are made of conductive material such as polysilicon. A thick oxide 151, in the gate trench 107 below gate electrode 150, reduces gate-drain capacitive coupling. Source and body metallizations 102 and 103 allow this active device to drive external connections. It is important to note that there is NO misalignment between the body contact region 136 and the gate trench 107.

In this example the field plate trench 109, but not the gate trench 107, has a p-type enhancement which creates a shield zone 114 around its bottom extremity. This enhances the field-shaping effect of the recessed field plate, to improve breakdown voltage. FIG. 1 also shows a local enhanced doping zone 115 at depths below the body junction. In this example, this enhanced doping zone 115 does not extend all the way down to the n/n+epi/substrate boundary. (However this is not necessarily the case in other embodiments.) The donor population which provides this enhanced doping zone 115 can be unpatterned, since the p-type shield diffusion 114 around the field plate trench will counterdope it in those locations.

FIG. 3A shows another example of a structure with NO misalignment between the body contact region and the gate trench. This is generally somewhat similar to the example of FIG. 1, except that there is a silicon dioxide layer on the top silicon surface. Furthermore, the doping additions 114 and 115 are not used, and the tungsten plug 182 does not make contact to the field plate 110 at the location shown. Instead, an insulator layer 383 (of e.g. silicon nitride or silicon dioxide) provides electrical separation here. Nevertheless, the p+ body contact regions 136 are still completely self-aligned to the gate trench 107, which gives very important advantages as described above.

FIG. 3B shows another example of a structure with NO misalignment between the body contact region and the gate trench. This is generally somewhat similar to the example of FIG. 3A, except that insulator layer 383 is not used.

FIG. 3C shows yet another example of a structure with NO misalignment between the body contact region and the gate trench. This is generally somewhat similar to the example of FIG. 3B, except for the shape of the tungsten plug. In this example the bottom part of the tungsten plug is still exactly aligned to the field plate, and the p+ body contact regions 136 are still precisely aligned to the field plate; but a recess has been etched above the body contact regions, to provide a wider part of the tungsten plug.

FIG. 3D shows still another example of a structure with NO misalignment between the body contact region and the gate trench. This is generally somewhat similar to the example of FIG. 3C, except for the shape of the p+ body contact regions 136. In this example an etchback was performed on the field plate trench before the acceptor implant which forms the regions 136, so they extend much deeper. However, the location of regions 136 is still completely defined by the location of the field plate trench.

FIG. 3E shows still another example of a structure with NO misalignment between the body contact region and the gate trench. This is generally somewhat similar to the example of FIG. 3D, except for the shape of the p− body regions 130. In this example an etchback was performed on the field plate trench before the acceptor implant which forms the regions 130, so they extend deeper at the RFP trench side.

FIG. 3F shows another example of a structure with NO misalignment between the body contact region and the gate trench. This is generally somewhat similar to the example of FIG. 3A, except for the presence of shield zone 114 and local enhanced doping zone 115, like those shown in FIG. 1.

FIG. 3G shows another example of a structure with NO misalignment between the body contact region and the gate trench. This is generally somewhat similar to the example of FIG. 3F, except for a slight etchback of the top of the gate electrode 150, the absence of insulator layer 383, and a deeper body contact 136 like that of FIG. 3D.

FIG. 3H shows another example of a structure with NO misalignment between the body contact region and the gate trench. This is generally somewhat similar to the example of FIG. 3G, except that the gate trench does not have a thicker bottom oxide (BOX).

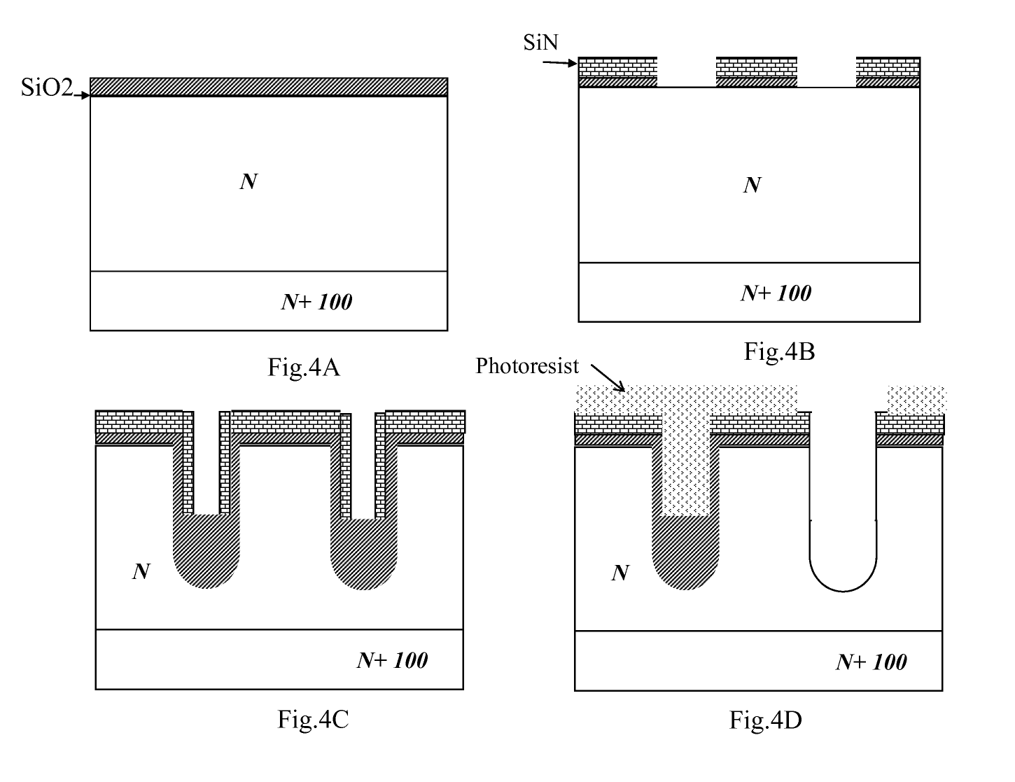

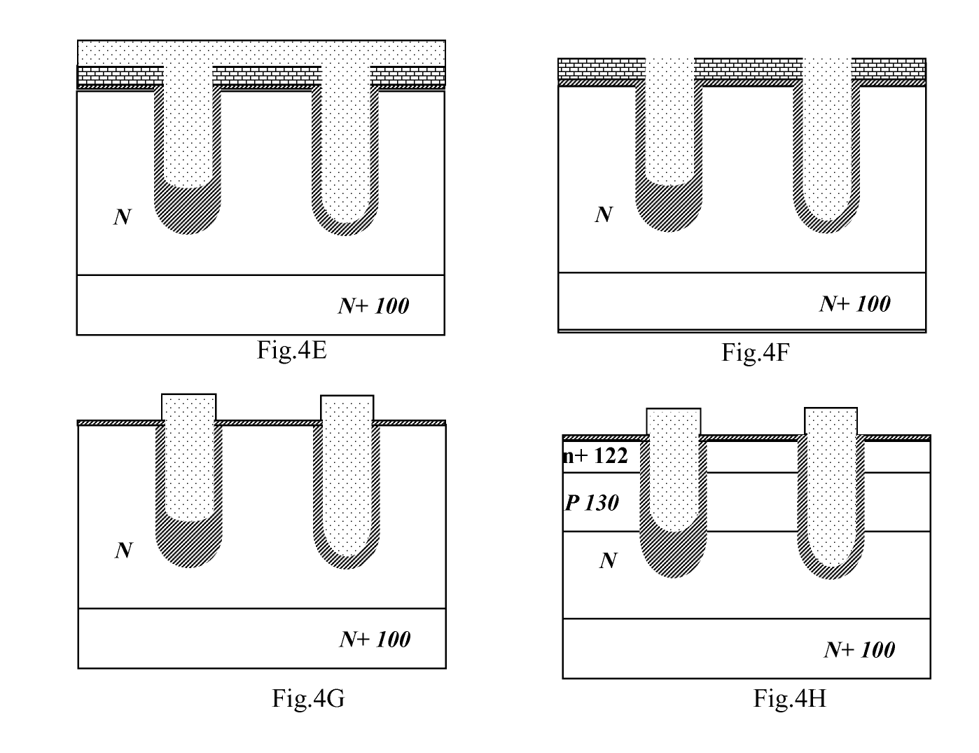

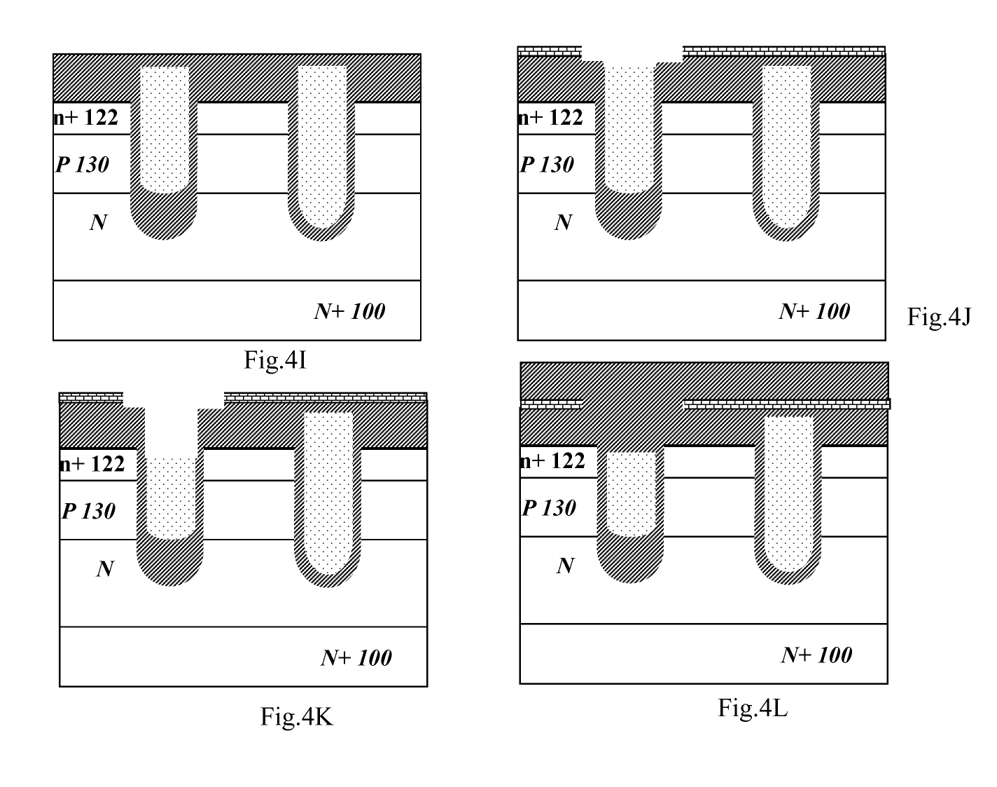

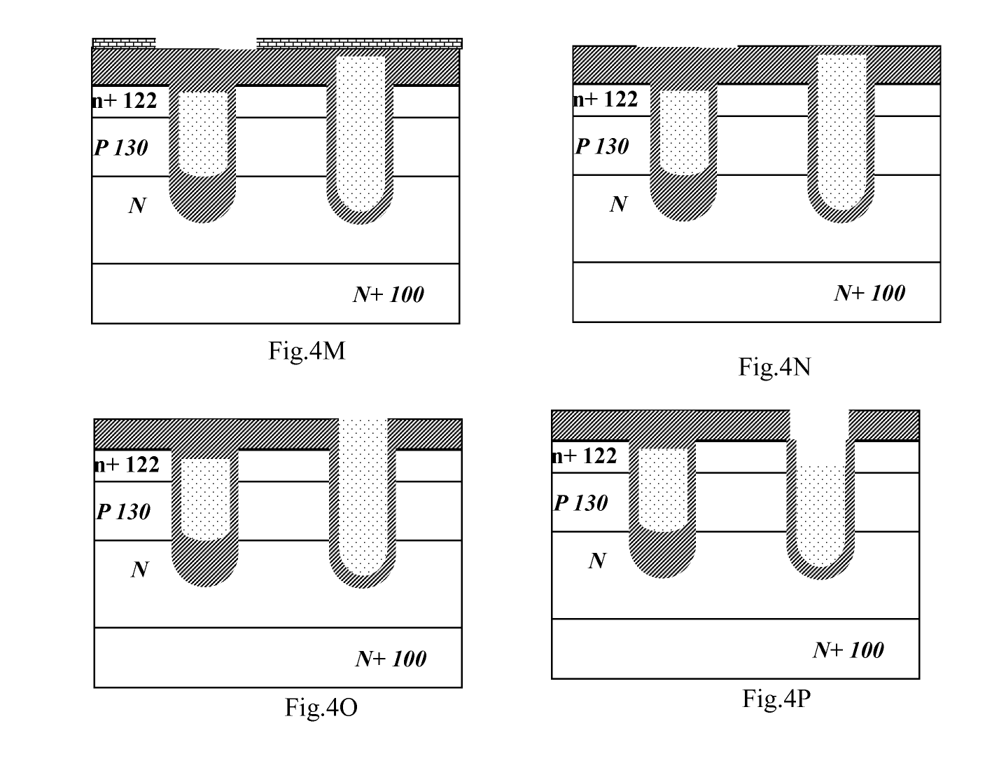

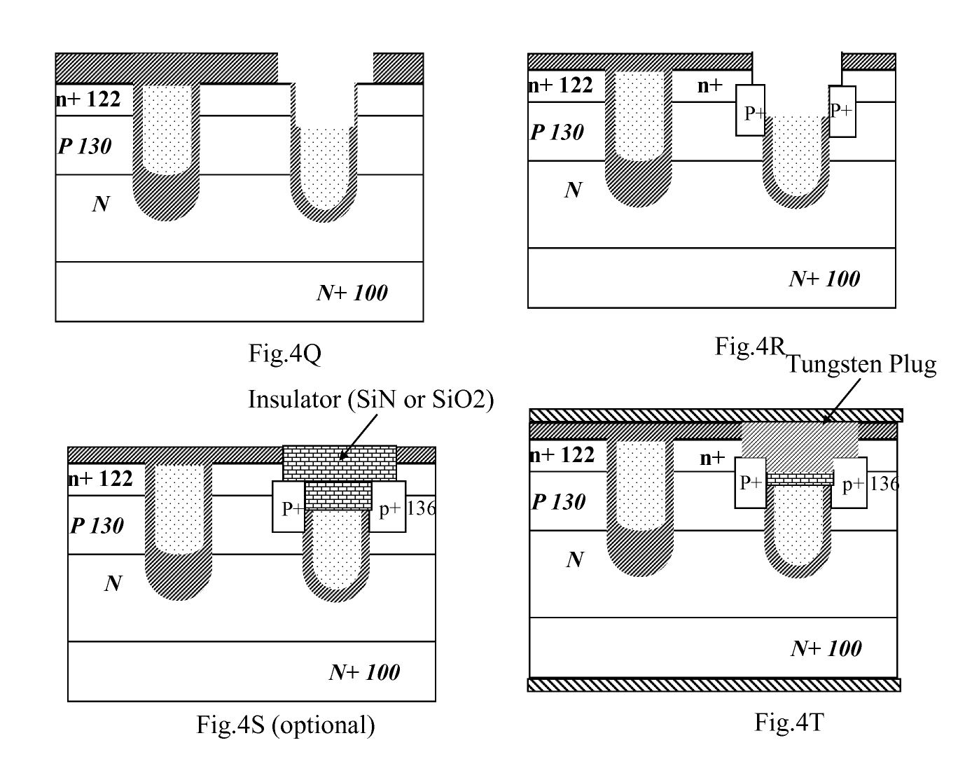

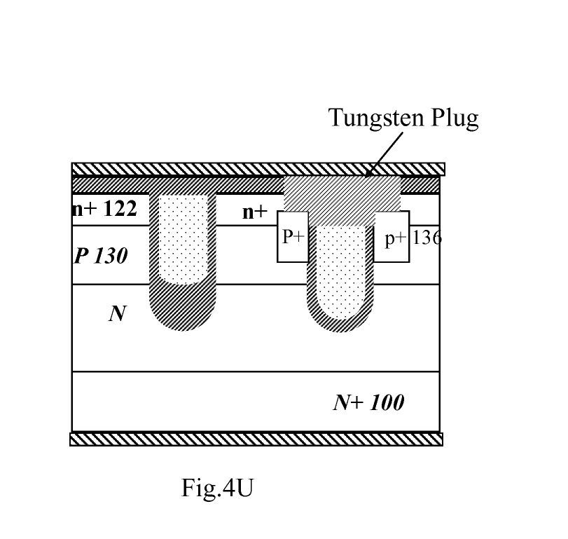

The sequence of Figures which starts with FIG. 4A shows fabrication methods.

The starting material is a heavily doped N+ silicon substrate doped for example with Phosphorus or Arsenic. An n-type epitaxial layer of silicon is grown on top of the N+ substrate. As shown in FIG. 4A an oxide layer is formed over the epitaxial layer.

A silicon nitride layer is then deposited on top of the oxide layer. The oxide layer for example can be 500 A-3000 A and the silicon nitride layer 1000 A-5000 A thick. These layers from a sacrificial hardmask layer which will play an important role in the following steps.

As shown in FIG. 4B a photoresist mask is used to etch the silicon nitride and oxide hardmask layers.

A trench is then etched in the locations exposed by the hardmask layers, and a thin thermal oxide layer is grown e.g. 200 A to 1000 A. A nitride layer is then deposited for example of a thickness of 100 A-1000 A. The nitride and oxide layer at the bottom of the trench are then etched using anisotropic dry etching and silicon is further etched. Thermal oxidation is used, so that the lower portion of the trench is completely oxidized as shown in FIG. 4C.

After removal of the nitride spacer and the pad oxide inside the trench, a photoresist mask is used to etch the thick bottom oxide from the RFP trench (but not the gate trench) as shown in FIG. 4D.

A thin gate-quality oxide is then grown in the gate and RFP trenches, and Polysilicon is deposited overall, as shown in FIG. 4E.

The polysilicon is then etched back to the height of the hardmask layers as shown in FIG. 4F. This can be done by a timed etch, or by CMP.

The remaining portions of the surface hardmask layers are then etched back to produce the intermediate structure shown in FIG. 4G. Note that the remaining polysilicon has provided “posts” which protrude up above the surface.

The N+ Source and P-body regions are implanted and driven-in using thermal or RTA techniques as shown in FIG. 4H.

An oxide layer (such as LTO) is deposited and etched using dry and/or wet etching or using Chemical Mechanical Polish (CMP). This produces the intermediate structure of FIG. 4I.

Another nitride (Silicon Nitride) layer is deposited and a photo resist mask is used to expose the polysilicon gate as shown in FIG. 4J.

The exposed polysilicon is etched back as illustrated in FIG. 4K, followed by an oxide layer deposition as shown in FIG. 4L.

CMP is then used to etch back the oxide, using the nitride layer as an etch stop layer. This is depicted in FIG. 4M.

The nitride layer is then removed (FIG. 4N), and an oxide etch is then performed to expose the polysilicon of the RFP trench as shown. This can be done in two slightly different ways.

FIG. 4O and FIG. 4P show one example, where a blanket oxide etch is performed to expose the polysilicon of the RFP trench, followed by a selective poly etchback. This produces a profile as shown in FIG. 4P.

FIG. 4Q shows use of an additional unmasked oxide etch, to expose a wider area around the polysilicon of the RFP trench. This additional etch can be performed on the intermediate structure of FIG. 4P in the sequence shown.

This additional unmasked oxide etch will produce a metal plug with a stepped width, as shown e.g in FIG. 3C. Alternatively, if this additional unmasked etch is omitted, the metal plug will have a more cylindrical shape, as shown e.g. in FIG. 3A.

After the structure of FIG. 4Q has been achieved, an angle implant of BF₂ is performed, followed (in this example) by a silicon etchback. This results in the intermediate structure of FIG. 4R. The silicon etchback produces a widened portion around the top of the field plate trench, but note that the location of the body contact regions 136 is defined only by the location of the original field plate trench, before this etchback. This patterned etch therefore does not introduce any alignment component into the critical spacing from p+ to gate.

FIG. 4S and FIG. 4T show an optional alternative which can be used at this point: in this alternative the contact open area is then filled with an insulating layer, such as nitride or silicon dioxide. Then, the insulator layer is recessed to expose N+ and P+ areas, and metallization is deposited. This results in the structure of FIG. 4T. This alternative can be useful, for example, where the field plate is biased separately from the source connection.

If the option of FIG. 4S is not used, then maerial for the metal plug is now deposited and planarized, followed by deposition of front and back metallizations 102 and 103. This results in the structure of FIG. 4U. Additional steps can now be performed to fabricated other elements if desired, and for other interconnect layers, passivation, bond pads, etc.

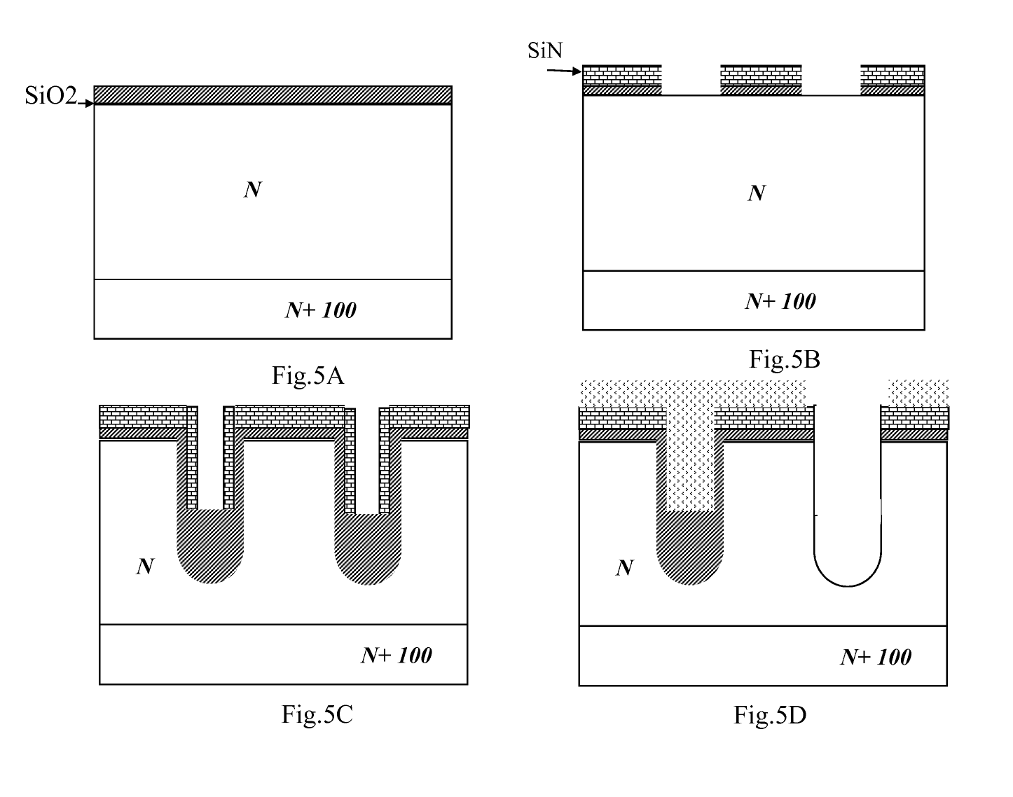

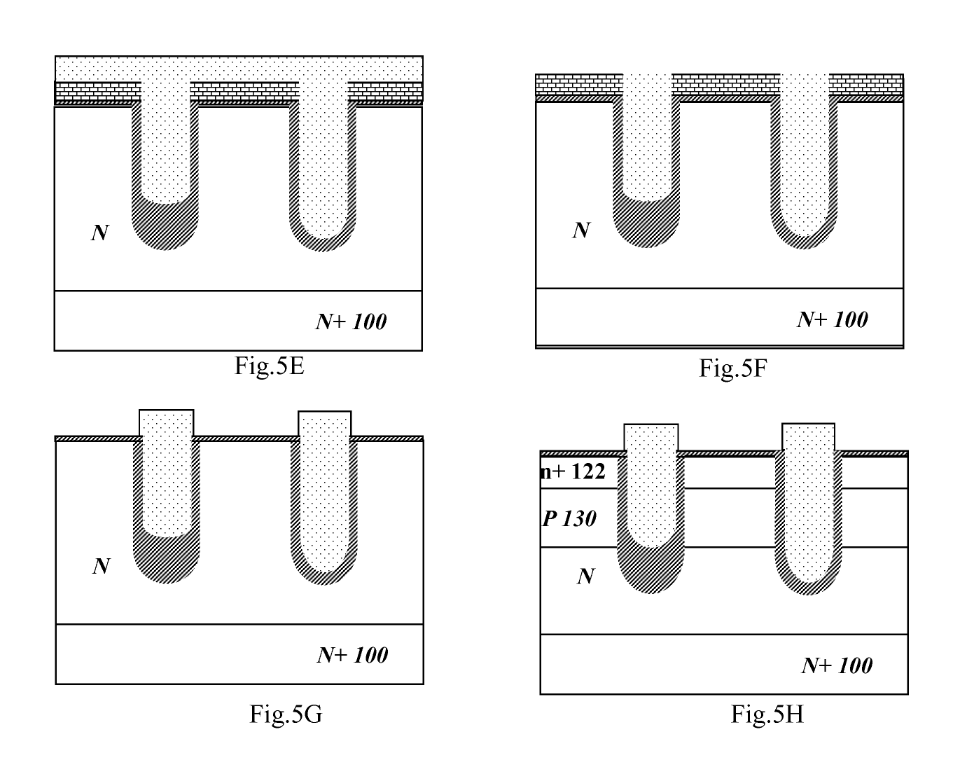

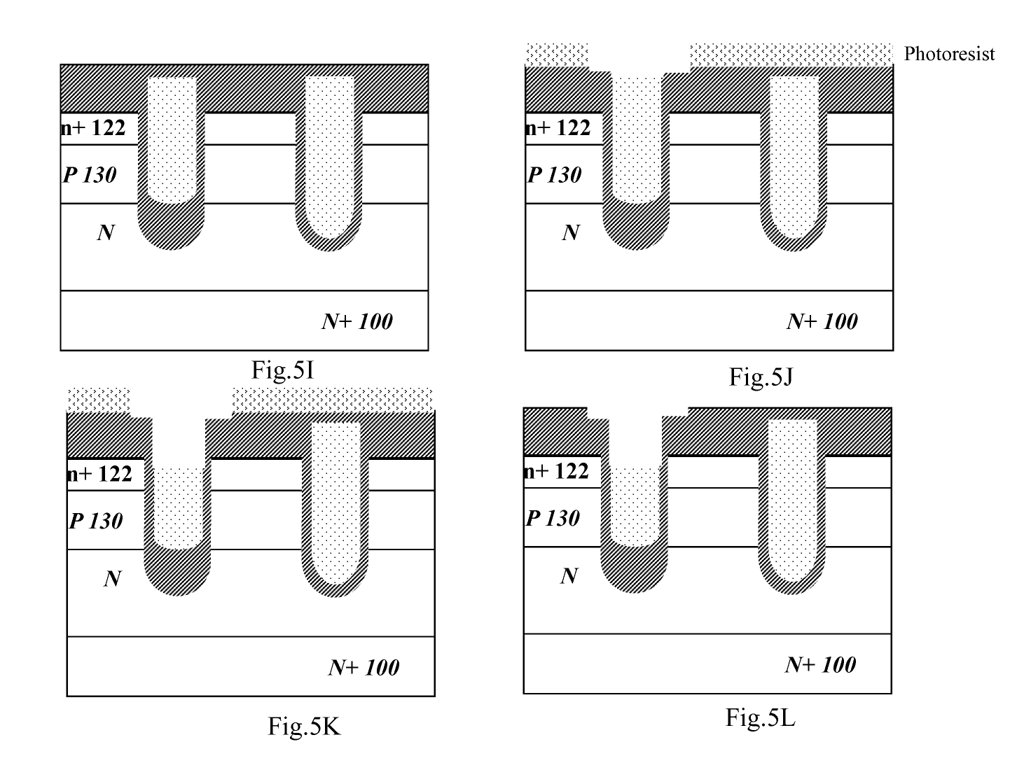

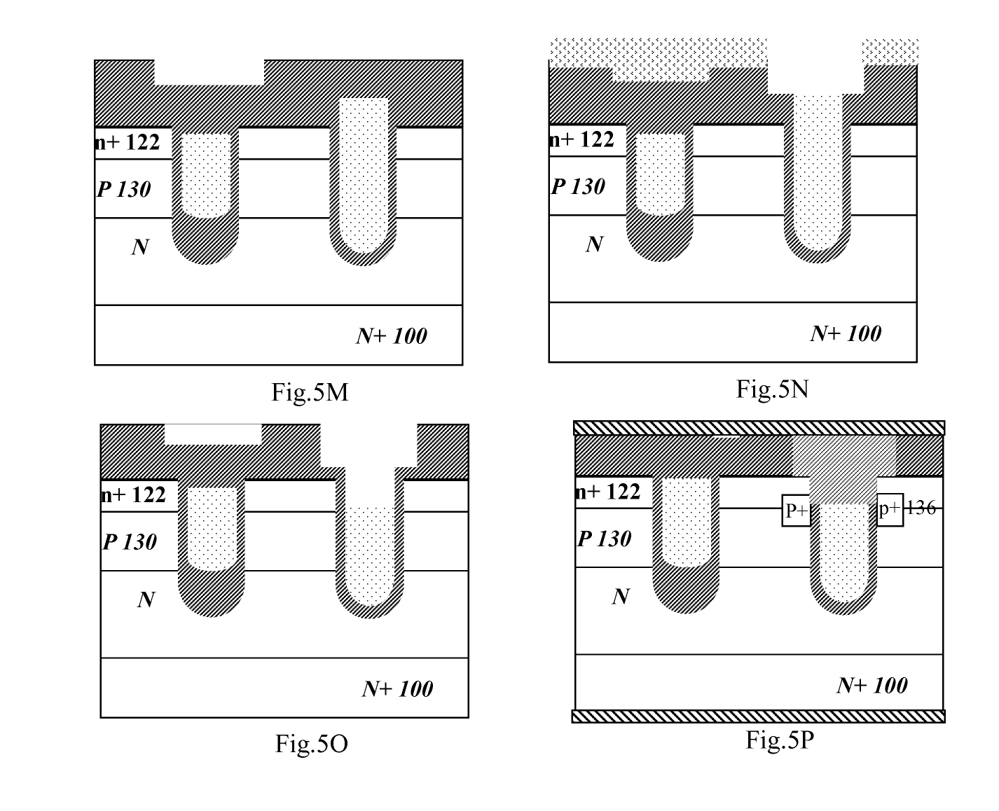

An alternative method for making the structure shown in FIG. 3A without using the CMP technique is described as shown in FIGS. 5A-5P.

FIGS. 5A-5I are identical to FIGS. 4A-4I. However, at this point the processes diverge. Instead of the hardmask deposition, removal, and oxide etchback steps shown in FIGS. 4J-4O, this sequence simply uses photoresist to expose the gate trenches (FIG. 5J and FIG. 5K), and, after processing of the gate trenches is completed (FIG. 5L and FIG. 5M), uses another photoresist step to expose the field plate trenches (FIG. 5N). Further processing of the field plate trenches (FIG. 5O) results in the structure shown in FIG. 5P.

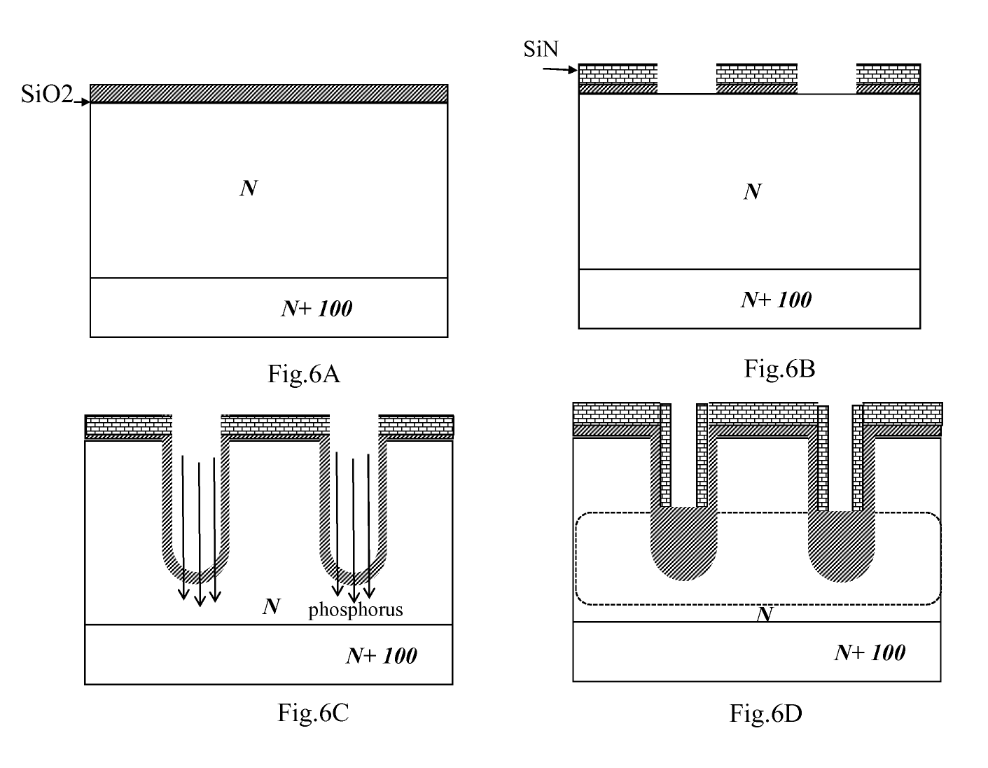

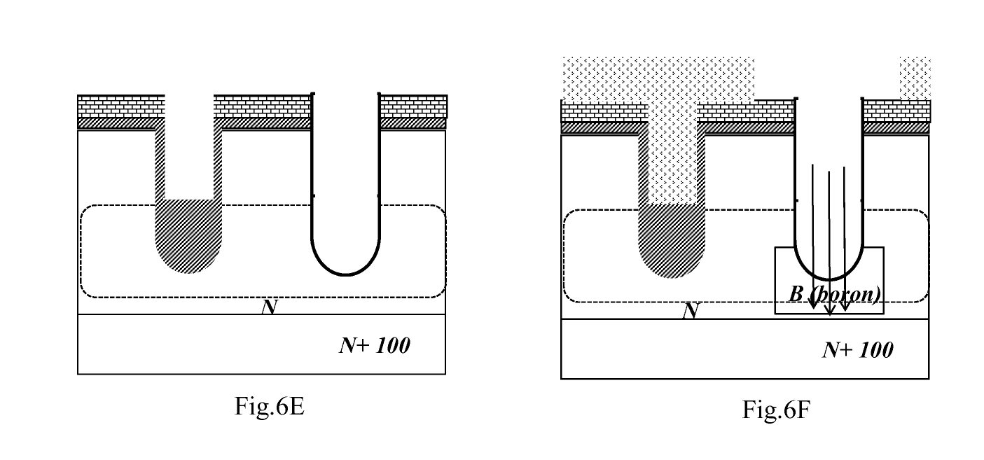

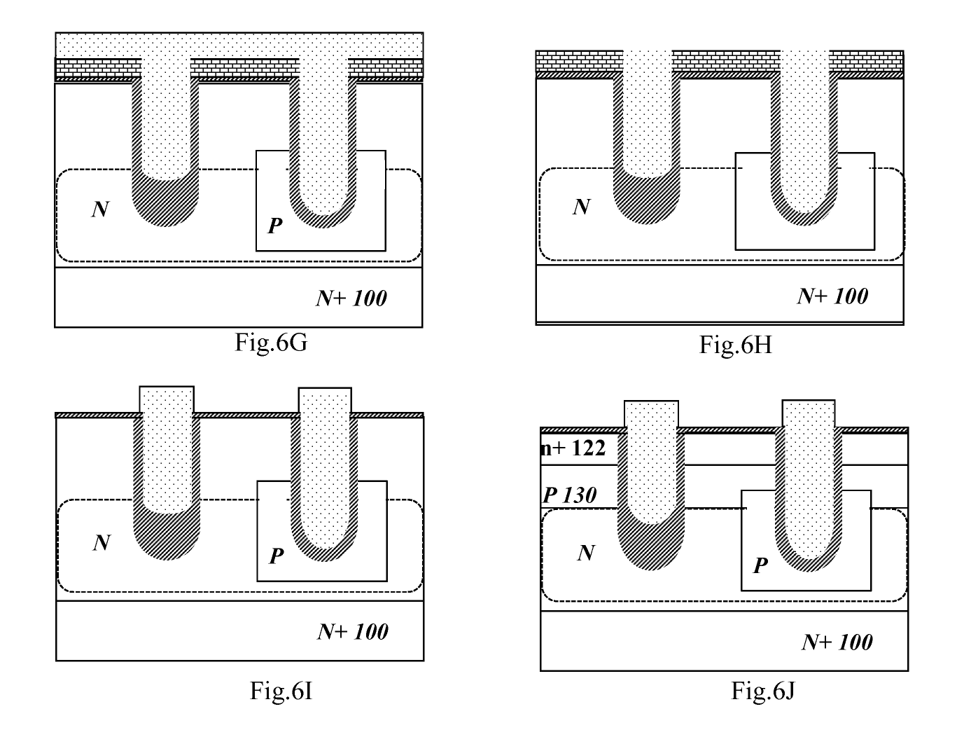

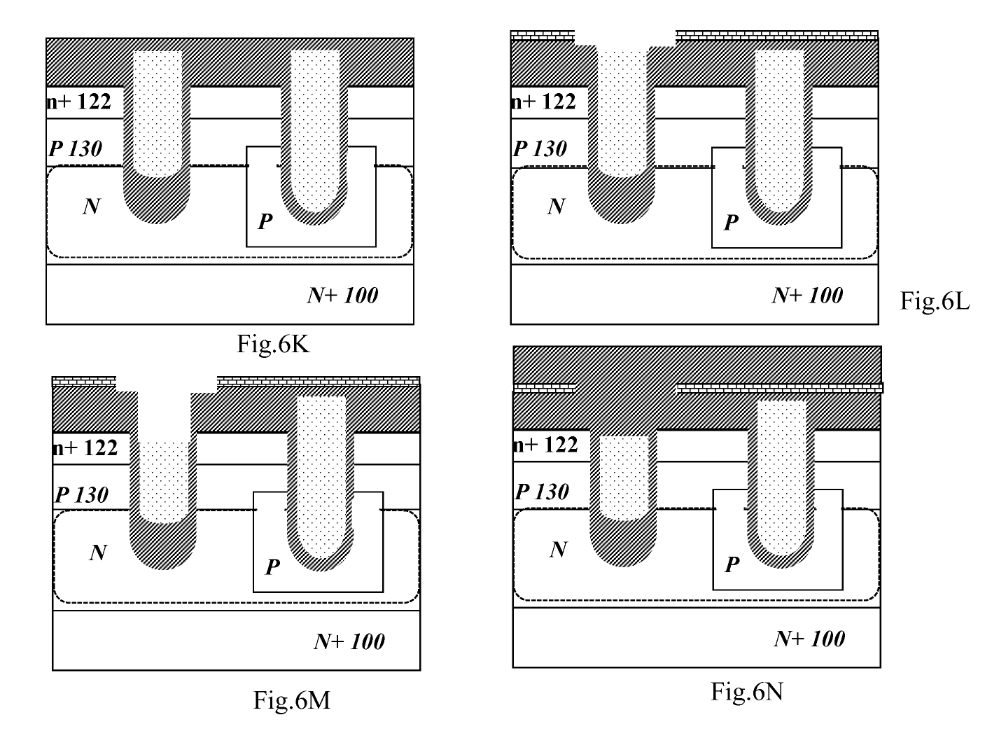

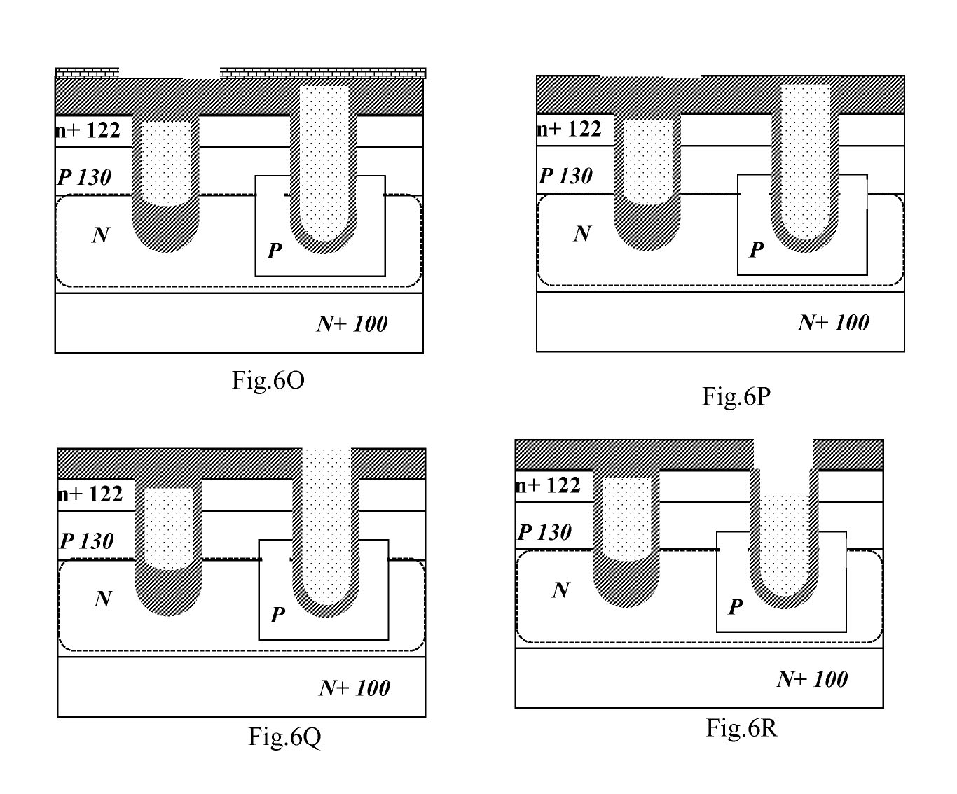

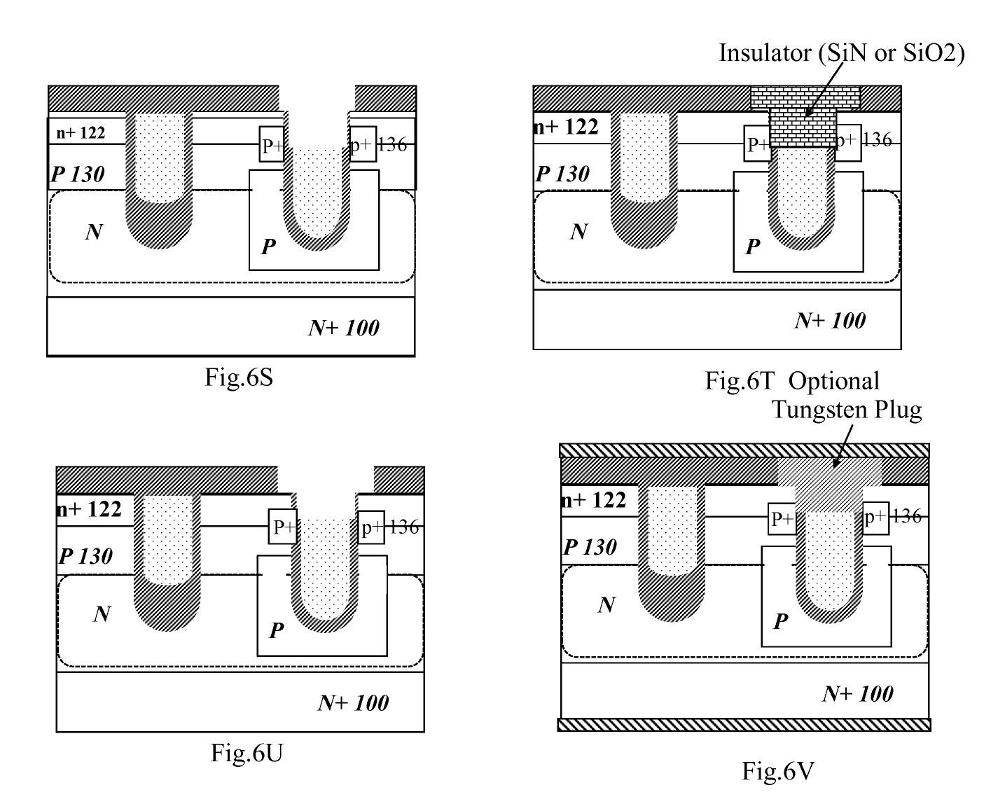

Further improvement on the device performance can be achieved by introducing local n-type doping enhancement implant and local p-type shield implant as shown in FIG. 1. A fabrication process flow to achieve this is shown in the sequence which begins with FIG. 6A.

FIG. 6A and FIG. 6B show steps which are almost the same as those of FIGS. 4A-4B, except that the epitaxial layer's doping can be lighter.

The choice of epitaxial layer thickness and doping will depend on the intended voltage rating of a particular device. For example, for a 60V rated device, the epitaxial layer can have a thickness of about 7 microns and a resistivity of about 0.6 ohm-cm. For a 30V rated device, the epi laer can have a thickness of about 4.5 microns and a resistivity of about 0.2 ohm-cm.

In FIG. 6C, note that a donor implant is performed into the open trenches. This will provide the local enhanced conductivity component 115. (An alternative method is to use graded or stepped in situ doping levels during epitaxial growth, to provide this doping enhancement region as a global component.)

FIG. 6D and FIG. 6E show steps which are similar to those described above, but note that in FIG. 6F a boron implant is performed into the open field plate trenches. This can be, for example, 10¹² to 10¹³ atoms per cm², at an energy of 20 to 400 keV. Multiple implant steps can also be employed. Considerations and alternatives for this implant are discussed at length in U.S. Pat. No. 8,076,719, which is hereby incorporated by reference in its entirety for all purposes.

The remainder of the Figures in this sequence (FIGS. 6F-6V) show steps which are generally similar to those in the sequences described above.

Other process parameters include an n+source implant dose of 4E15 to 1E16 ions per cm², at an energy of e.g. 30-100 keV. The P− body implant can be, for example, boron at a dose of 5E12 to 1E14/cm², and an energy of 60 to 120 keV. The implant for the body contact region can be, for example, boron at a dose of 1E15-6E15/cm², and an energy of 20 keV to 120 keV. Multiple implant steps can be used.

The disclosed innovations, in various embodiments, provide one or more of at least the following advantages. However, not all of these advantages result from every one of the innovations disclosed, and this list of advantages does not limit the various claimed inventions.
Simpler fabrication;
Denser layout;
Higher current capacity for a given area;
Lower cost for a given capacity; and/or
Improved ruggedness.

According to some but not necessarily all disclosed innovative embodiments, there is provided: A method of fabricating a semiconductor device, comprising the steps, in any order, of: a) etching first and second trenches, simultaneously, into a semiconductor mass; b) filling said first and second trenches, simultaneously, with a conductive material, while said semiconductor mass is overlaid by a sacrificial layer; c) removing said sacrificial layer to expose pillars of said conductive material which rise above said semiconductor mass; d) etching back said conductive material, over said first trench, to form a gate electrode therein; e) forming a first-conductivity-type source region, and a second-conductivity-type body region therebelow, in said semiconductor mass; and f) etching said conductive material over said second trench to form a cavity, introducing second-conductivity-type dopants to form body contact regions which are self-aligned to said second trench, and forming a metallic material in said cavity to provide a self-aligned contact to said body contact regions.

According to some but not necessarily all disclosed innovative embodiments, there is provided: A method of fabricating a semiconductor device, comprising the steps, in any order, of: a) etching first and second trenches, simultaneously, into a semiconductor mass; b) filling said first and second trenches, simultaneously, with a solid material, while said semiconductor mass is overlaid by a sacrificial layer; c) removing said sacrificial layer to expose pillars of said solid material which rise above said semiconductor mass; d) etching back said solid material, over said first trench, and forming a gate electrode therein; e) forming a first-conductivity-type source region and a second-conductivity-type body region in said semiconductor mass where said body region lies below said source region; and f) etching back said conductive material over said second trench to form a cavity, introducing second-conductivity-type dopants into said cavity to thereby form body contact regions which are self-aligned to said second trench, and forming a metallic material in said cavity to connect to said body contact regions; whereby the spacing between said body contact region and said gate electrode does not depend at all on lithographic misalignment.

According to some but not necessarily all disclosed innovative embodiments, there is provided: A semiconductor device, comprising: source, body, drift, and drain regions, wherein said body region has a conductivity type opposite to those of said source and drain regions; a conductive gate electrode in a first trench, which is electrostatically coupled, in at least some locations, to selectably invert a portion of said body region which adjoins said first trench; a conductive field plate in a second trench; wherein said first and second trenches having been formed by a single patterning step, and have no misalignment therebetween; and a body contact region, having the same conductivity type as said body region, which is self-aligned to said second trench, independently of alignment variations; whereby said body contact region also has a spacing, from said first trench, which is independent of any alignment variations.

According to some but not necessarily all disclosed innovative embodiments, there is provided: Methods and resulting device structures for power trench transistor fabrication, wherein a reachup pillar from the field plate trench is left in place to define the location of a self-aligned contact to the field plate.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

All the above variants of the structure can be realized in stripe or cellular layout such as square, rectangular, hexagonal or circular layouts.

The invention is equally applicable to p-channel MOSFETs where the polarities of the layers and permanent charge are reversed.

Even though the embodiments above are for MOSFET structures, the inventions are applicable to other devices such as Insulated Gate Bipolar Transistors (IGBTs), thyristors, and other devices that can block voltages.

For another example, the semiconductor material does not necessarily have to be silicon, as in the preferred embodiment. This can alternatively be SiGe or SiGeC or other Group IV semiconductor alloy.

It is understood that numerous combinations of the above embodiments can be realized.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A method of fabricating a semiconductor device, comprising the steps, in any order, of:
a) etching first and second trenches, simultaneously, into a semiconductor mass;
b) filling said first and second trenches, simultaneously, with a conductive material, while said semiconductor mass is overlaid by a sacrificial layer;
c) removing said sacrificial layer to expose pillars of said conductive material which rise above said semiconductor mass;
d) etching back said conductive material, over said first trench, to form a gate electrode therein;
e) forming a first-conductivity-type source region, and a second-conductivity-type body region therebelow, in said semiconductor mass; and
f) etching said conductive material over said second trench to form a cavity, introducing second-conductivity-type dopants to form body contact regions which are self-aligned to said second trench, and forming a metallic material in said cavity to provide a self-aligned contact to said body contact regions.

2. The method of claim 1, further comprising the additional step, after said step a), of forming a dielectric, at the bottom of said first trench, which is thicker than the dielectric at the bottom of said second trench.

3. The method of claim 1, wherein said semiconductor mass is silicon.

4. The method of claim 1, wherein said metallic material also makes electrical contact to said field plate.

5. The method of claim 1, wherein said conductive material is doped polysilicon.

6. The method of claim 1, wherein said first conductivity type is n-type, and said second conductivity type is p-type.

7. The method of claim 1, further comprising the additional step, prior to said step b), of growing a thin dielectric layer on sidewalls of said trenches.

8. The method of claim 1, wherein said gate electrode is entirely recessed below the surface of said semiconductor mass.

9. A method of fabricating a semiconductor device, comprising the steps, in any order, of:
a) etching first and second trenches, simultaneously, into a semiconductor mass;
b) filling said first and second trenches, simultaneously, with a solid material, while said semiconductor mass is overlaid by a sacrificial layer;
c) removing said sacrificial layer to expose pillars of said solid material which rise above said semiconductor mass;
d) etching back said solid material, over said first trench, and forming a gate electrode therein;
e) forming a first-conductivity-type source region and a second-conductivity-type body region in said semiconductor mass where said body region lies below said source region; and
f) etching back said conductive material over said second trench to form a cavity, introducing second-conductivity-type dopants into said cavity to thereby form body contact regions which are self-aligned to said second trench, and forming a metallic material in said cavity to connect to said body contact regions;
whereby the spacing between said body contact region and said gate electrode does not depend at all on lithographic misalignment.

10. The method of claim 9, wherein, in said step b), said solid material is never removed entirely from said first trench, and provides the material for said gate electrode.

11. The method of claim 9, further comprising the additional step, after said step a), of forming a dielectric, at the bottom of said first trench, which is thicker than the dielectric at the bottom of said second trench.

12. The method of claim 9, further comprising the additional step of forming a second-conductivity-type body region below said first-conductivity-type source region in said semiconductor mass.

13. The method of claim 10, further comprising the additional step of forming a second-conductivity-type body region below said first-conductivity-type source region in said semiconductor mass.

14. The method of claim 9, wherein said semiconductor mass is silicon.

15. The method of claim 9, wherein said first conductivity type is n-type, and said second conductivity type is p-type.

16. The method of claim 9, wherein said solid material is doped polysilicon.

17. The method of claim 9, further comprising the additional step, prior to said step b), of growing a thin dielectric layer on sidewalls of said trenches.

18. A semiconductor device, comprising:
source, body, drift, and drain regions, wherein said body region has a conductivity type opposite to those of said source and drain regions;
a conductive gate electrode in a first trench, which is electrostatically coupled, in at least some locations, to selectably invert a portion of said body region which adjoins said first trench;
a conductive field plate in a second trench; wherein said first and second trenches having been formed by a single patterning step, and have no misalignment therebetween;
and a body contact region, having the same conductivity type as said body region, which is self-aligned to said second trench, independently of alignment variations;
whereby said body contact region also has a spacing, from said first trench, which is independent of any alignment variations.

19. A plurality of semiconductor devices according to claim 18.

20. The device of claim 19, wherein said semiconductor mass is silicon.

21-29. (canceled)
